(19) United States
(12) Patent Application Publication
(10) Pub. No.: US 2025/0158351 A1
(43) Pub. Date: May 15, 2025

(54) RADIATION-EMITTING COMPONENT AND METHOD FOR PRODUCING A RADIATION-EMITTING COMPONENT

(71) Applicant: ams-OSRAM International GmbH, Regensburg (DE)

(72) Inventors: Wolfgang NEUMANN, Regensburg (DE); Sabine VOM DORP, Altdorf b. Nürnberg (DE); Andreas REITH, Steinach (DE)

(21) Appl. No.: 18/836,056

(22) PCT Filed: Dec. 7, 2022
(86) PCT No.: PCT/EP2022/084859

§ 371 Date: Aug. 6, 2024

(30) Foreign Application Priority Data
Feb. 7, 2022 (DE) 10 2022 201 253.4

(51) Int. Cl. H01S 5/02257; H01S 5/02315; H01S 5/042

(52) U.S. Cl. CPC H01S 5/02257; H01S 5/02315; H01S 5/0421

(57) ABSTRACT

A radiation-emitting device includes a carrier formed to include sapphire and/or AlN. A semiconductor layer sequence is applied onto the carrier. A radiation outcoupling layer is arranged on the side of the carrier facing away from the semiconductor layer sequence, wherein the semiconductor layer sequence includes an active region for generating electromagnetic radiation, and wherein the radiation outcoupling layer has a refractive index for the electromagnetic radiation generated by the active region which is between the refractive index of the carrier and the refractive index of the medium surrounding the component. The radiation outcoupling layer is based on quartz glass. Furthermore, a method for manufacturing an optoelectronic device is disclosed.

### RELATED APPLICATIONS

This application is a US National Stage of International Application PCT/EP2022/084859, filed on 7 Dec. 2022 and claims priority under 35 U.S.C. § 119(a) and 35 U.S.C. § 365(b) from German patent application DE 10 2022 201 253.4 filed on 7 Feb. 2022, the contents of which are incorporated herein by reference in their entirety FIELD Various embodiments of the present disclosure relate to a radiation-emitting device and a method of manufacturing a radiation-emitting device.

### SUMMARY

Aspects of the present disclosure can relate to a radiation-emitting device that may be operated particularly efficiently. Furthermore, various embodiments relate to manufacturing methods by use of which a particularly efficient radiation-emitting device may be manufactured particularly efficiently.

According to at least one embodiment of the radiation-emitting device, the radiation-emitting device comprises a carrier formed to comprise sapphire and/or AlN. The carrier may be a mechanically supporting component of the radiation-emitting device. The carrier may be a three-dimensional body which has at least approximately the shape of a cuboid, a cylinder or a disk, for example. The carrier has a main extension plane. For example, the main extension plane of the carrier runs, at least in parts, parallel to a surface, for example a cover surface, of the carrier. The carrier may have a thickness in a direction perpendicular to the main extension plane.

The carrier may consist of or contain a growth substrate. The carrier may comprise sapphire. Furthermore, the carrier may comprise AlN. For example, the carrier comprises sapphire and an AlN buffer layer applied onto the sapphire. Alternatively, the carrier may comprise only one of these materials. For example, the carrier may comprise only sapphire or only AlN.

The carrier may comprise a patterning. The patterning may be formed on an outer surface of the carrier, for example. Alternatively, the carrier may have a patterning at a layer transition within the carrier. For example, at a transition from a sapphire substrate to an AlN buffer layer. The patterned carrier is, for example, a carrier that comprises a pre-patterned sapphire. Furthermore, the carrier may also be patterned in the manufacturing process of the radiation-emitting device. In particular, the patterning may be a periodic patterning comprising elevations and depressions that are arranged at regular intervals.

According to at least one embodiment, the radiation-emitting device comprises a semiconductor layer sequence applied onto the carrier. The semiconductor layer sequence is, for example, epitaxially deposited on the carrier. In particular, the semiconductor layer sequence may be arranged only on one side of the carrier. The semiconductor layer sequence may comprise at least one layer; more specifically, the semiconductor layer sequence comprises several layers. These may comprise the same materials, or different materials, respectively. The semiconductor layer sequence comprises, for example, an n-doped semiconductor layer, a p-doped semiconductor layer and an active region. In particular, the n-doped semiconductor layer may face the carrier. The active region is arranged, for example, between the n-doped semiconductor layer and the p-doped semiconductor layer. In particular, the active region may comprise a multiple quantum well structure. The active region is configured, for example, to emit electromagnetic radiation. The emitted radiation is, for example, in the wavelength range between IR radiation and UV radiation. In particular, the emitted radiation may be radiation of wavelengths within the UV range. The active region may, for example, comprise a III-V semiconductor material. In particular, the radiation-emitting device may be a light-emitting diode or a laser diode.

According to at least one embodiment of the radiation-emitting device, the radiation-emitting device comprises a radiation outcoupling layer, which is arranged on the side of the carrier facing away from the semiconductor layer sequence. In particular, the radiation outcoupling layer is transparent to the radiation emitted by the active region.

Furthermore, the radiation outcoupling layer forms a surface of the radiation-emitting device, for example. This means that no other layer associated with the radiation-emitting device is applied onto the radiation outcoupling layer. An outer surface of the radiation outcoupling layer may therefore face the surrounding medium. The surface of the radiation outcoupling layer facing away from the carrier therefore represents, for example, an interface between the radiation-emitting device and the surrounding medium. The side of the radiation outcoupling layer facing away from the carrier may, in particular, be smooth, rough or patterned. The side of the radiation outcoupling layer facing the carrier may, in particular, follow the surface properties of the carrier. This may mean that the side of the radiation outcoupling layer facing the carrier may be complementary to a pattern of the carrier. In particular, the side of the radiation outcoupling layer facing the carrier may be in direct contact with the carrier in its entirety.

According to at least one embodiment of the radiation-emitting device, the radiation outcoupling layer has a refractive index for the electromagnetic radiation generated by the active region. The refractive index is between a refractive index of the carrier and a refractive index of a medium surrounding the device.

Owing to the radiation outcoupling layer, it is possible to have less of the electromagnetic radiation emitted by the active region reflected back into the radiation-emitting device than would be the case without the radiation outcoupling layer. This is achieved by the fact that the radiation outcoupling layer has a refractive index that is between the refractive index of the carrier and the refractive index of the surrounding medium. This results in less refraction and less back-reflection of the electromagnetic radiation during transition of the electromagnetic radiation from the carrier to the radiation outcoupling layer and during transition from the radiation outcoupling layer to the surrounding medium. The radiation outcoupling layer allows the radiation emitted by the active region to be outcoupled more efficiently from the radiation-emitting device.

As used herein, “surrounding” means that the medium is arranged around the device at least in one direction of radiation of the radiation-emitting device. The surrounding medium may, for example, completely surround the radiation-emitting device. The surrounding medium is therefore a medium in which the radiation-emitting device is operated. The medium may comprise air or a potting material, for example. The radiation direction of the radiation-emitting device is, for example, a direction that is at least partially perpendicular to a main extension plane of the radiation-emitting device.

According to at least one embodiment of the radiation-emitting device, the radiation outcoupling layer is based on quartz glass. The refractive index of quartz glass may be between the refractive index of the carrier and the refractive index of the surrounding medium, particularly for the electromagnetic radiation generated during operation. The surrounding medium may, in particular, be air. Quartz glass has high transmittance for a large range of the electromagnetic spectrum, for example, especially for the UV range.

According to at least one embodiment of the radiation-emitting device, the radiation-emitting device comprises a substrate formed to comprise sapphire and/or AlN, a semiconductor layer sequence applied onto the substrate, a radiation outcoupling layer, which is arranged on the side of the carrier facing away from the semiconductor layer sequence, wherein the semiconductor layer sequence comprises an active region for generating electromagnetic radiation, and the radiation outcoupling layer has a refractive index for the electromagnetic radiation generated by the active region, the refractive index being between the refractive index of the carrier and the refractive index of the medium surrounding the device, and the radiation outcoupling layer is based on quartz glass.

Radiation-emitting devices may comprise a lens for outcoupling radiation. The lens may be made of polymers, for example expensive fluoropolymer lenses. Such a lens is bonded to the radiation-emitting device using an organic adhesive. One disadvantage of such a radiation-emitting device is that the use of an organic adhesive leads to a short service life of the radiation-emitting device, especially if it emits UV radiation when operated.

The radiation-emitting device described herein is based, among other things, on the concept that a higher light yield may be achieved using the radiation outcoupling layer that is based on quartz glass, as the adaptation of the refractive indices reduces refraction and/or back-reflection of the emitted electromagnetic radiation. In the radiation-emitting device described herein, there is no organic adhesive between the carrier and the radiation outcoupling layer. Furthermore, quartz glass is particularly resistant to ageing, especially when irradiated with UV radiation. Thus, the radiation-emitting device does not comprise any substance susceptible to the electromagnetic radiation emitted by the active region, which may result in a longer service life of the radiation-emitting device. The radiation-emitting device described herein may thus be operated in an efficient manner.

According to at least one embodiment, the active region is adapted to generate electromagnetic radiation within the UV range. The UV range comprises wavelengths within the range from 100 nm to 400 nm. One advantage of this embodiment is that the radiation outcoupling layer based on quartz glass exhibits high transparency in the UV range. The active region may be based on AlGaN, for example.

According to at least one embodiment, the side of the carrier facing and/or facing away from the radiation outcoupling layer is patterned. In this case, for example, the carrier comprises a pattern only on the side facing the radiation outcoupling layer or, for example, only on the side facing away from the radiation outcoupling layer. Alternatively, the carrier may be patterned on both sides. For example, the patterned carrier may be or comprise a pre-patterned sapphire.

One advantage of the embodiment described herein is that the patterning of the carrier reduces reflection of the electromagnetic radiation generated by the active region during transition into the carrier or during transition from the carrier to the radiation outcoupling layer. A further advantage is that the patterning of the carrier enables better adhesion of the radiation outcoupling layer to the carrier.

According to at least one embodiment, the side of the radiation outcoupling layer facing away from the carrier is roughened. In particular, the side of the radiation outcoupling layer facing away from the carrier is the side of the radiation outcoupling layer facing the surrounding medium. The electromagnetic radiation generated by the active region may be outcoupled from the radiation-emitting device into the surrounding medium through the side of the radiation outcoupling layer facing away from the carrier. The side of the radiation outcoupling layer facing away from the carrier may, for example, be roughened by means of random roughening, laser lithography, nano-precision lithography, sandblasting or etching. In particular, the roughening may be nanopatterning. One advantage of roughening the side of the radiation outcoupling layer facing away from the carrier is that the radiation outcoupling efficiency of the radiation-emitting device may be increased.

According to at least one embodiment, the radiation outcoupling layer comprises or forms an optical element on the carrier. The optical element may be an optical lens. The optical lens comprises, for example, a spherical structure, a Fresnel structure, a microlens array or a diffractive optical element. The optical element may be configured to shape the electromagnetic radiation passing through the optical element. For example, the radiation may be bundled or scattered by the radiation outcoupling layer. One concept of this embodiment is that the radiation exiting the radiation-emitting device may be shaped. For example, the radiation may be bundled or scattered. This allows for the radiation to be shaped at chip level.

According to at least one embodiment, a bonding layer is arranged between the carrier and the radiation outcoupling layer, and the bonding layer comprises or consists of SiO₂. One advantage is that the bonding layer both adheres well to the carrier and enables good adhesion of the radiation outcoupling layer.

According to at least one embodiment, contacts for external contacting are arranged on the side of the semiconductor layer sequence facing away from the radiation outcoupling layer. In particular, the contacts may be arranged exclusively on this side. In particular, this may therefore constitute a rear-side contacting. The radiation-emitting device may therefore be a flip-chip device. Furthermore, the n-contact may surround the p-contact in a frame-like manner, for example. One advantage of this embodiment is that the radiation generated by the active region is not reflected by metallic contacts in one direction of radiation.

According to at least one embodiment, a metallization is applied onto the side of the semiconductor layer sequence facing away from the carrier. The metallization may be configured to reflect the electromagnetic radiation generated by the active region. The metallization may therefore serve as a mirror for the electromagnetic radiation generated by the active region. For example, the metallization exhibits high reflectivity for the electromagnetic radiation generated. Herein, high reflectivity means, for example, a reflectivity of at least 90%, in particular at least 99%.

The metallization may be rhodium, aluminum and/or gold, for example. These materials exhibit high reflectivity for electromagnetic radiation in the UV range. Alternatively, any other metal or any other material that is suitable for reflecting the electromagnetic radiation generated by the active region may be used for the metallization. The metallization may also be electrically conductive; especially if the metallization is arranged between the semiconductor layer sequence and the p-contact, the metallization may be electrically conductive. One concept of this embodiment is that the emitted electromagnetic radiation can, for example, exit the device in one radiation direction. The metallization can allow the electromagnetic radiation to be reflected in a preferred radiation direction.

According to at least one embodiment, the carrier has a thickness of at most 400 μm, in particular at most 150 μm. The height of the complete radiation-emitting device may thus be in the range from 150 μm to 500 μm, for example. The thickness of the carrier may, for example, be at least 50 μm, in particular at least 100 μm. One advantage of the above embodiment is that it allows for more compact devices. More compact radiation-emitting devices have the advantage that they may be used in several device arrangements.

Furthermore, a method of manufacturing an optoelectronic device is disclosed. The optoelectronic device may, for example, be manufactured by a method described herein. In other words, all features disclosed for the optoelectronic device are also disclosed for the method of manufacturing an optoelectronic device and vice versa.

According to at least one embodiment of the method for manufacturing a radiation-emitting device, the method comprises a process step in which a substrate formed to comprise sapphire and/or AlN is provided.

According to at least one embodiment of the method, the method comprises a method step in which a semiconductor layer sequence is applied onto the substrate. In particular, the semiconductor layer sequence may be grown epitaxially.

According to at least one embodiment of the method, the method comprises a step in which a radiation outcoupling layer based on quartz glass is formed on the side of the substrate facing away from the semiconductor layer sequence.

According to at least one embodiment of the method for manufacturing a radiation-emitting device, a substrate formed to comprise sapphire and/or AlN is provided. A semiconductor layer sequence is epitaxially grown thereon. A radiation outcoupling layer based on quartz glass is formed on the side of the substrate facing away from the semiconductor layer sequence. One advantage of this embodiment of a manufacturing process is that a radiation-emitting device may be manufactured efficiently.

According to at least one embodiment of the process for manufacturing a radiation-emitting device, forming the radiation outcoupling layer based on quartz glass comprises a process step in which a starting layer comprising SiO₂ particles in a matrix material is applied onto the side of the substrate facing away from the semiconductor layer sequence. In a subsequent process step, the matrix material is removed. This is followed by a process step in which the SiO₂ particles are sintered to produce a radiation outcoupling layer based on quartz glass.

The starting layer contains particles in a matrix material. The particles may be nanoparticles, in particular SiO₂ nanoparticles. The matrix material comprises a polymer, for example. The matrix material is removed in a debinding step. The starting layer is heated to a temperature that is suitable for annealing the matrix material. For a polymer, for example, the required temperature may be between 400° C. and 800° C. The particles remaining on the carrier are then sintered. This means that the particles are heated, which may lead to compaction and/or fusion of the particles, for example. For SiO₂ particles, for example, the required temperature may be at least 1000° C., in particular at least 1300° C. One advantage of this embodiment is that the radiation outcoupling layer may be applied directly in a front-end process. The radiation outcoupling layer may therefore be formed directly on the carrier. This means that impurities may at least be reduced.

According to at least one embodiment, the matrix material comprises a polymer. One advantage of this embodiment is that polymers are easy to process. They may be suitable for injection molding, spin-on coating, casting, 3D printing, subtractive machining or replication processes, for example. The starting layer may therefore be a glass suitable for injection molding, for example. Polymers may also be debound from the starting layer, which enables further processing of the particles remaining in the starting layer.

According to at least one embodiment, the method comprises a process step in which the substrate is thinned directly after the semiconductor layer sequence has been applied onto the substrate. One advantage of thinning the substrate is that a smaller, more compact design of a radiation-emitting device may be achieved.

According to at least one embodiment, a curvature of the carrier is reduced by means of stress reduction by inducing impurities or defects in the carrier with the aid of a laser. The carrier is a sapphire carrier, for example. The stress caused by the epitaxial growth of further layers on the sapphire carrier may be absorbed in the laser-treated layer within the sapphire carrier. One advantage of this embodiment is that the stress is reduced and cracks in the epitaxially grown layers are reduced or prevented.

According to at least one embodiment of a method for manufacturing a radiation-emitting device, after epitaxially growing the semiconductor layer sequence on the substrate, an auxiliary carrier is applied onto the semiconductor layer sequence on the side of the semiconductor layer sequence facing away from the substrate. The substrate is then thinned. After the radiation outcoupling layer has been formed, a further auxiliary carrier is applied onto the radiation outcoupling layer and the auxiliary carrier is removed. Furthermore, metallic contacts are formed on the side of the semiconductor layer sequence facing away from the radiation outcoupling layer and the additional auxiliary carrier is removed.

The auxiliary carrier and the additional auxiliary carrier are mechanically supporting elements. The auxiliary carriers may comprise borosilicate glass, calcium acetate or sapphire glass, among others. One advantage of this embodiment is that the substrate may be made thinner by using auxiliary carriers in the manufacturing process. As a result, more compact designs of the radiation-emitting device are achieved.

According to at least one embodiment of the method, after forming the radiation outcoupling layer, metal webs are applied onto the substrate in spaces of the radiation outcoupling layer, the further auxiliary carrier has a structure which is complementary to a structure of the radiation outcoupling layer, the further auxiliary carrier has metal webs in places, and the metal webs of the further auxiliary carrier are connected to the metal webs of the substrate. The metal webs are applied by means of sputtering using a mask, for example. The metal webs applied onto the substrate include AuSn, for example. The metal webs applied to the other auxiliary carrier include gold, for example. In the case of a lenticular radiation outcoupling surface, the metal webs on the substrate are, in particular, applied onto the substrate between the lenses. In the case of a further auxiliary carrier that is complementary to a lenticular radiation outcoupling surface, the metal webs on the further auxiliary carrier are, in particular, applied onto the spaces between the lenticular structures. One advantage of this embodiment is that the radiation outcoupling layer may be formed to be patterned and a thinner substrate may be used by using the auxiliary carriers in the manufacturing process. An auxiliary carrier that is complementary to a structure of the radiation outcoupling surface also provides better mechanical support for the device and may be bonded to the substrate more easily. With AuSn:Au wafer bonding, the additional auxiliary carrier may be easily applied and removed again. As this may be carried out using non-invasive methods, the carrier may, in particular, be reused.

According to at least one embodiment, the method comprises a step in which the starting layer is applied onto the substrate in a patterned manner such that it has lenticular structures. The starting layer may, for example, be applied to have a lenticular structure by means of replication processes or 3D printing. The starting layer may be applied directly in a lenticular shape, for example. Alternatively, the starting layer may also be patterned in a lenticular shape only after it has been applied onto the substrate.

According to at least one embodiment of the method, notches are made in the substrate before the starting layer is applied onto the substrate, and the notches serve as stop edges for forming the lenticular structures. The notches are formed, for example, by mechanical processing, in particular by sawing or lasering. The starting layer, which is sprayed on for example, spreads out on the substrate up to the notches and forms a lenticular structure. One advantage of this embodiment is that the process for obtaining lenticular structures is simplified.

According to at least one embodiment, the substrate is patterned before the starting layer is applied. The substrate may be patterned at a layer transition within the substrate. Alternatively, external surfaces that extend parallel to a main extension plane of the substrate may be patterned.

One advantage of this embodiment is the improved adhesion of the starting layer on the substrate. A further advantage is that total reflection of the radiation generated by the active region is reduced by the patterned surfaces. The patterning may, for example, be a nanopatterning, such as a roughening.

### BRIEF DESCRIPTION OF THE DRAWINGS

In the following, the optoelectronic device described herein and the method described herein for manufacturing an optoelectronic device are explained in more detail in conjunction with embodiments and the associated figures.

FIGS. 1 to 9 show schematic cross-sections through a radiation-emitting device according to an example embodiment.

FIGS. 10A to 10G show process steps in a method for manufacturing a radiation-emitting device according to an example embodiment.

FIGS. 11A-11M show an embodiment of a method for manufacturing a radiation-emitting device.

FIGS. 12A-12C show a further embodiment of a method for manufacturing a radiation-emitting device.

FIGS. 13A and 13B show a method for manufacturing a radiation-emitting device according to an example embodiment.

FIGS. 14A-14I show an embodiment of a method for manufacturing a plurality of radiation-emitting devices.

### DETAILED DESCRIPTION

In the figures, elements that are identical, similar or have the same effect are denoted by the same reference numerals. The figures and the proportions of the elements shown in the figures are not to be regarded as being to scale. Rather, individual elements may be shown at an exaggerated scale for better visualization and/or better comprehensibility.

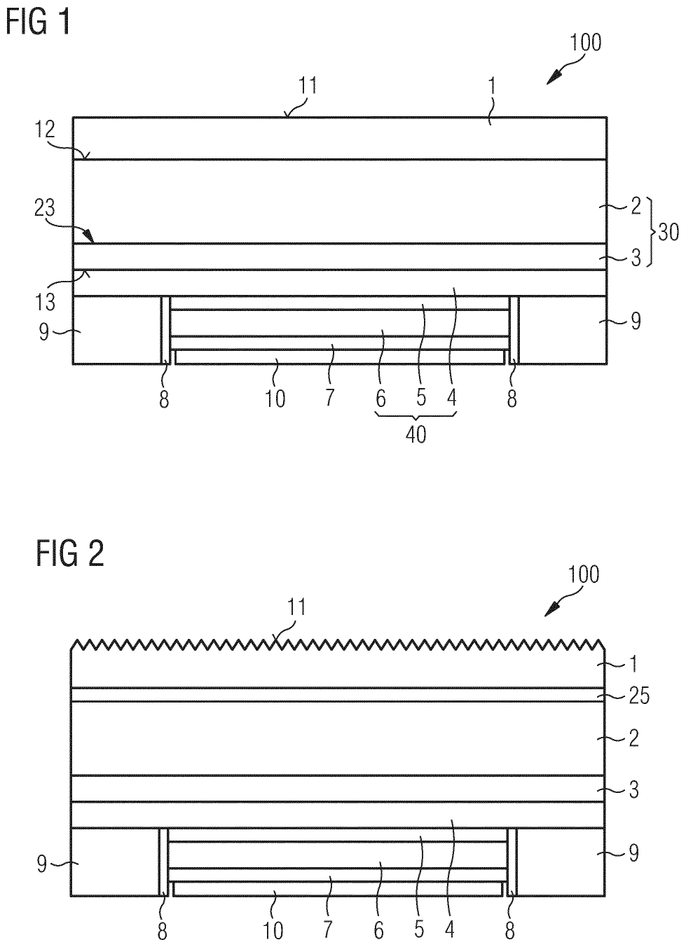

FIG. 1 shows a sectional view of a radiation-emitting device 100 according to an example embodiment. The radiation-emitting device 100 comprises a carrier 30. The carrier may be formed to comprise several layers. A radiation outcoupling layer 1 is applied onto the carrier 30 on an upper side 12 of the carrier 30. In the illustrated example embodiment, the carrier 30 exhibits a two-layer structure. For example, the carrier 30 comprises a sapphire carrier 2 and a buffer layer 3. The two layers of the carrier are connected to each other by a layer transition 23. A semiconductor layer sequence 40 is epitaxially grown on the buffer layer 3. The buffer layer 3 serves in particular to adapt the lattice constant of the carrier 30 and the lattice constant of the semiconductor layer sequence 40 in order to enable optimum growth of the semiconductor layer sequence 40 on the carrier 30.

The semiconductor layer sequence 40 comprises an n-doped semiconductor layer 4, an active region 5 and a p-doped semiconductor layer 6. A metallization 7 is applied onto the p-doped semiconductor layer 6. The metallization 7 may, for example, comprise rhodium, aluminum and/or gold.

A p-contact 10 is arranged on the metallization 7. The p-contact 10 serves to electrically contact the p-doped semiconductor layer 6. Parts of the n-doped semiconductor layer 4 are not covered with the other layers of the semiconductor layer sequence 40. At least one n-contact 9 for electrical contacting of the n-doped semiconductor layer 4 is arranged on these exposed areas of the n-doped semiconductor layer 4. The metallic contacts (9, 10) for external contacting may therefore be arranged in particular on the side of the semiconductor layer sequence 40 facing away from the radiation outcoupling layer 1. The two n-contacts 9 shown may be connected to each other and, in particular, may be arranged in a frame around the p-contact 10. The n-contact 9 may, for example, completely enclose the p-contact 10 laterally. A passivation layer 8 is arranged between the n-contact 9 and the active region 5, the p-doped semiconductor layer 6, the metallization 7 and the p-contact 10.

FIG. 2 shows a sectional view of a radiation-emitting device 100. The radiation-emitting device 100 according to the example embodiment shown in FIG. 2 differs from the radiation-emitting device 100 according to the example embodiment shown in FIG. 1 in that the exposed surface 11 of the radiation outcoupling layer 1 is patterned. The patterning of the exposed surface 11 is in particular a nanopatterning. This means that the exposed surface 11 may be roughened. FIG. 2 also comprises a bonding layer 25. The bonding layer 25 may, for example, include SiO₂.

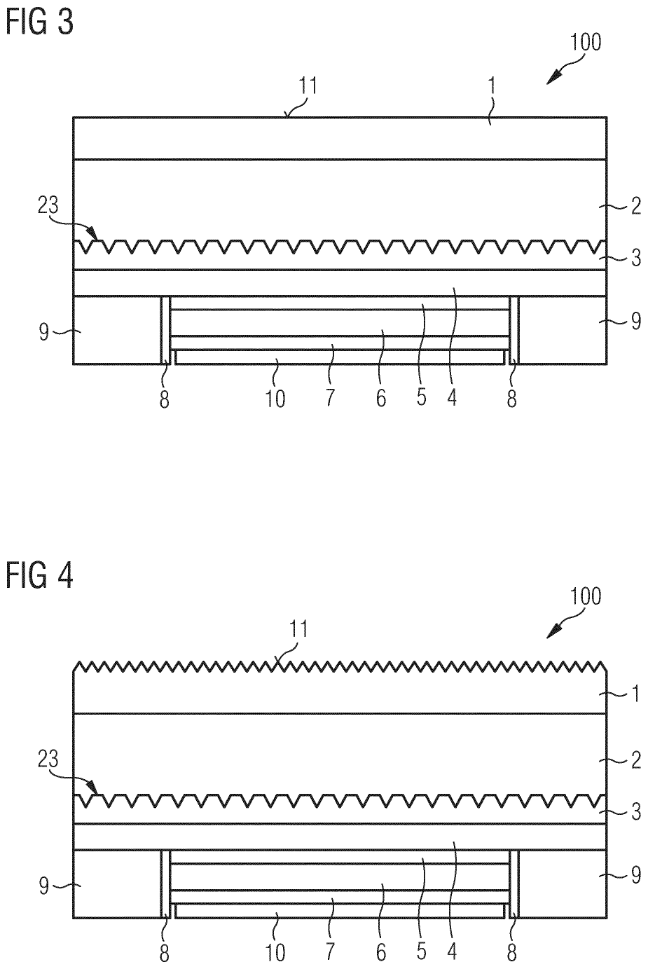

FIG. 3 shows a sectional view of a radiation-emitting device 100. The radiation-emitting device 100 according to the example embodiment shown in FIG. 3 differs from the radiation-emitting device 100 according to the example embodiment shown in FIG. 1 in that a layer transition 23 in the carrier 30 comprises a patterning.

FIG. 4 shows a sectional view of a radiation-emitting device 100 according to an example embodiment that differs from the example embodiment shown in FIG. 1 in that the exposed surface 11 of the radiation outcoupling layer 1 is roughened and the layer transition 23 in the carrier 30 is patterned.

FIG. 5 shows a sectional view of a radiation-emitting device 100 according to an example embodiment which, in contrast to the example embodiment of a radiation-emitting device 100 shown in FIG. 3, also comprises a patterned top side 12 of the carrier 30.

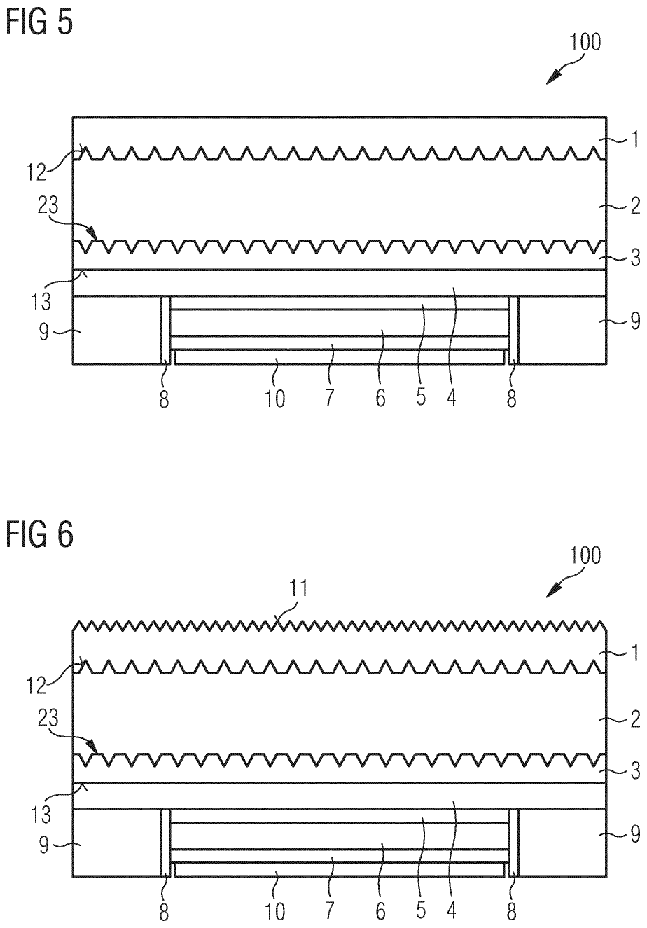

FIG. 6 shows a radiation-emitting device 100 according to an example embodiment that differs from the radiation-emitting device 100 in FIG. 4 in that a top side 12 of the carrier 30 is patterned also.

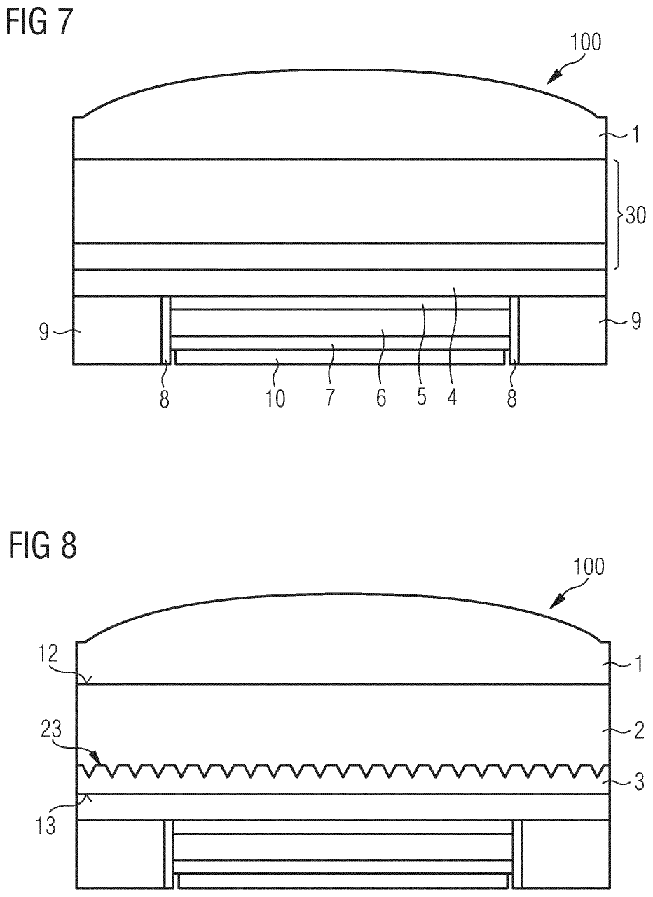

The radiation-emitting device 100 shown in FIG. 7 corresponds to the structure of the radiation-emitting device shown in FIG. 1, with the radiation outcoupling layer 1 being applied to the carrier 30 as an optical element. In the example embodiment of FIG. 7, the radiation outcoupling layer 1 is, in particular, shaped as a convex lens. Alternatively, not shown, the curved region of the lens may extend to the side of the carrier 30 facing away from the semiconductor layer sequence.

FIG. 8 shows an example embodiment of a radiation-emitting device 100 which differs from the example embodiment of the radiation-emitting device 100 of FIG. 7 in that the layer transition 23 is patterned.

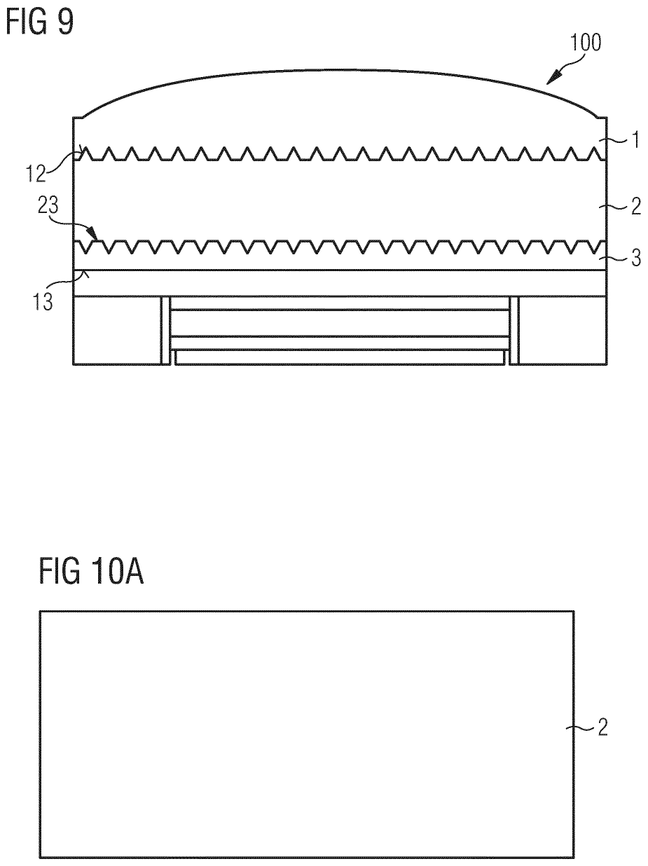

The example embodiment of a radiation-emitting device 100 shown in FIG. 9 comprises a patterned surface 12 in addition to the patterned layer transition 23 of the radiation-emitting device 100 shown in FIG. 8.

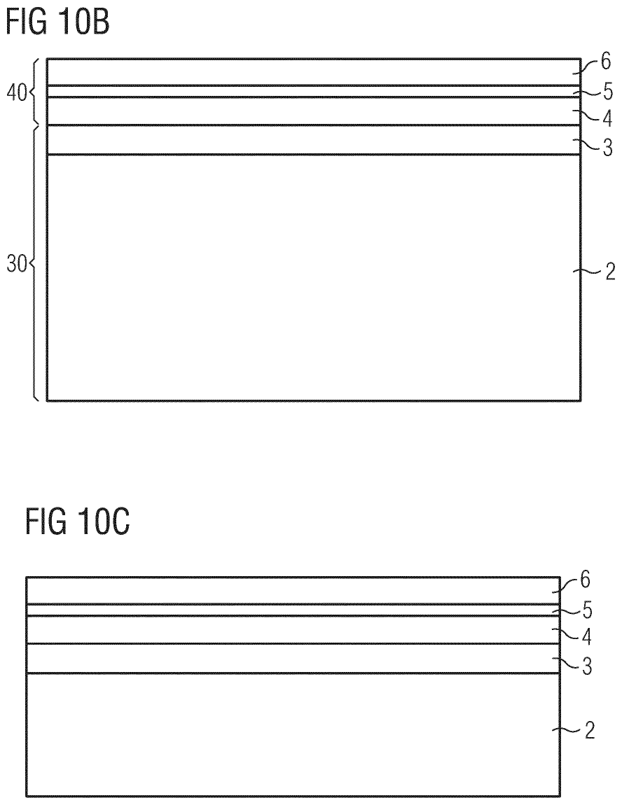

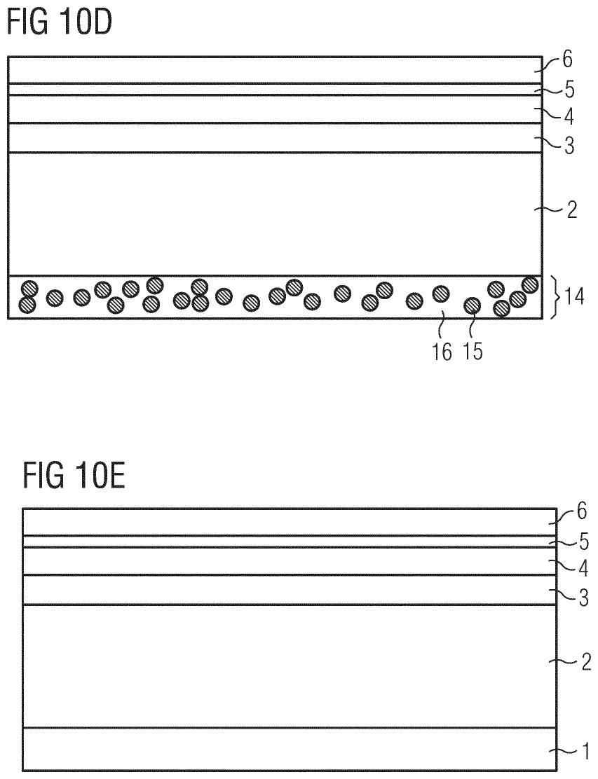

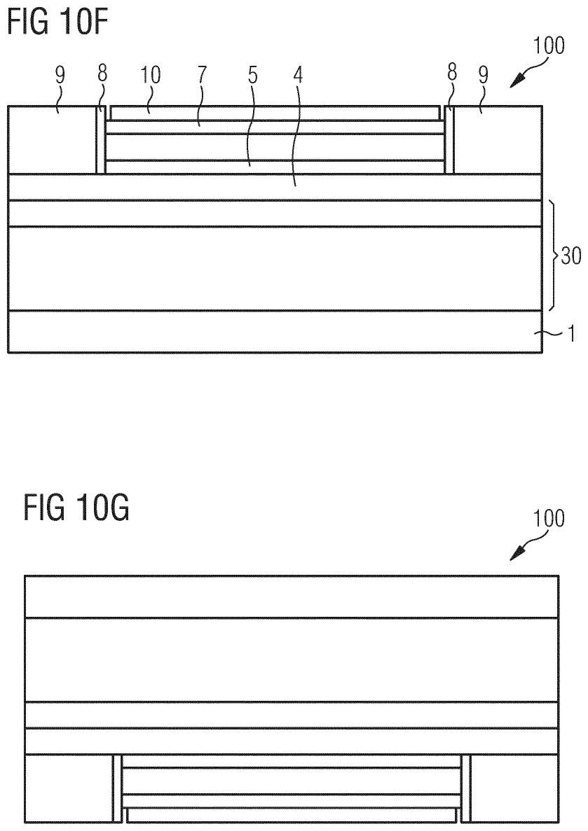

FIGS. 10A, 10B, 10C, 10D, 10E, 10F, 10G show process steps in a method of manufacturing a radiation-emitting device according to an example embodiment.

In a first process step, FIG. 10A, a sapphire carrier 2 is provided. The sapphire carrier 2 may constitute the carrier 30. Alternatively, at least one further layer applied to the sapphire may also form part of the carrier 30. In particular, the layers of the carrier 30 may be sapphire and/or AlN.

In a next process step, FIG. 10B, a semiconductor layer sequence 40 is applied onto the carrier 30. The semiconductor layer sequence 40 is, for example, epitaxially deposited on the carrier 30. First, the n-doped semiconductor layer 4, then the active region 5 and then the p-doped semiconductor layer 6 are grown onto the substrate 30. In the example embodiment shown in FIG. 10B, the carrier 30 comprises two layers containing different materials.

FIG. 10C shows the radiation-emitting device 100 after a process step in which the carrier 30 is thinned. The sapphire layer 2 of the carrier 30 is thinned, for example, by means of chemical mechanical polishing. The target thickness may, for example, be a maximum of 400 μm, in particular a maximum of 350 μm.

In a subsequent step, FIG. 10D, a starting layer 14 is applied onto the side of the carrier 30 facing away from the semiconductor layer sequence 40. The starting layer 14 includes SiO₂ particles 15 in a matrix material 16. The matrix material 16 comprises a polymer, for example. The SiO₂ particles 15 may, in particular, exhibit sizes in the nanometer range. The SiO₂ particles are, for example, more densely packed than shown in FIG. 10D.

In order to obtain a radiation-emitting device 100 as shown in FIG. 10E in the manufacturing method starting from FIG. 10D, the matrix material 16 is first removed from the starting layer 14. The SiO2 particles 15 remaining in the starting layer 14 are then sintered to form a radiation outcoupling layer 1. Herein, sintering means that at least the SiO₂ particles are temperature-treated. For example, the SiO₂ particles 15 are heated to a temperature above the melting point, for example to 1300° C., in order to compact the SiO₂ particles 15 into a radiation outcoupling layer 1 based on quartz glass. The matrix material 16 may be removed from the starting layer 14 directly in the sintering process, for example. Alternatively, the matrix material 16 may be removed from the starting layer 14 in a debinding step before the sintering process. In this case, the starting layer 14 is first heated to a temperature that is suitable for annealing the matrix material 16. The required temperature may be 400-800° C., for example; in particular, the matrix material may be removed from the starting layer 14 at 600° C.

FIG. 10F shows the radiation-emitting device 100 after a method step in which the radiation-emitting device 100 is electrically contacted. The method step comprises exposing parts of the surface of the n-doped semiconductor layer 4 facing away from the carrier 30, as well as side surfaces of the p-doped semiconductor layer 6 and the active region 5. The exposing may be carried out by means of lithography or etching, for example.

The method step further comprises applying a metallization 7. The metallization may comprise rhodium, aluminum or gold and may serve as a mirror for the electromagnetic radiation generated by the active region 5.

A passivation layer 8 is applied onto the side surfaces of the active region 5, the p-doped semiconductor layer 6 and the metallization 7. A p-contact 10 is arranged on the metallization 7 for electrical contacting. An n-contact 9 is attached to the n-doped semiconductor layer 4 for electrical contacting. In the example embodiment shown, the metallic contacts are arranged on a surface of the n-doped semiconductor layer 4 and the metallization 7 that faces away from the radiation outcoupling surface 1.

In particular, the contacts may be arranged exclusively on this side. The radiation-emitting device 100 may therefore be a flip-chip device. Furthermore, the n-contact 9 may surround the p-contact 10 in a frame-like manner.

FIG. 10G shows a finished radiation-emitting device 100 according to an embodiment example.

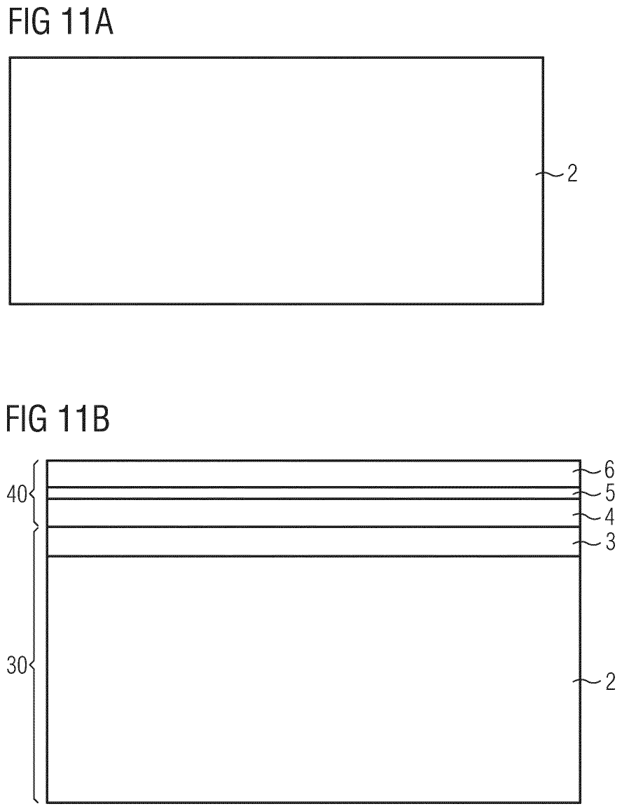

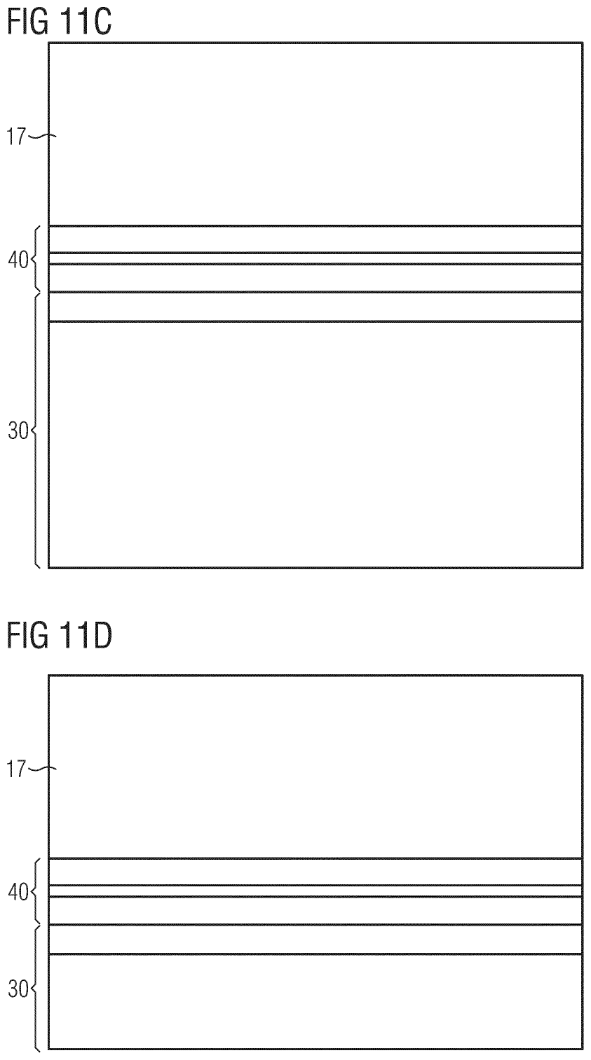

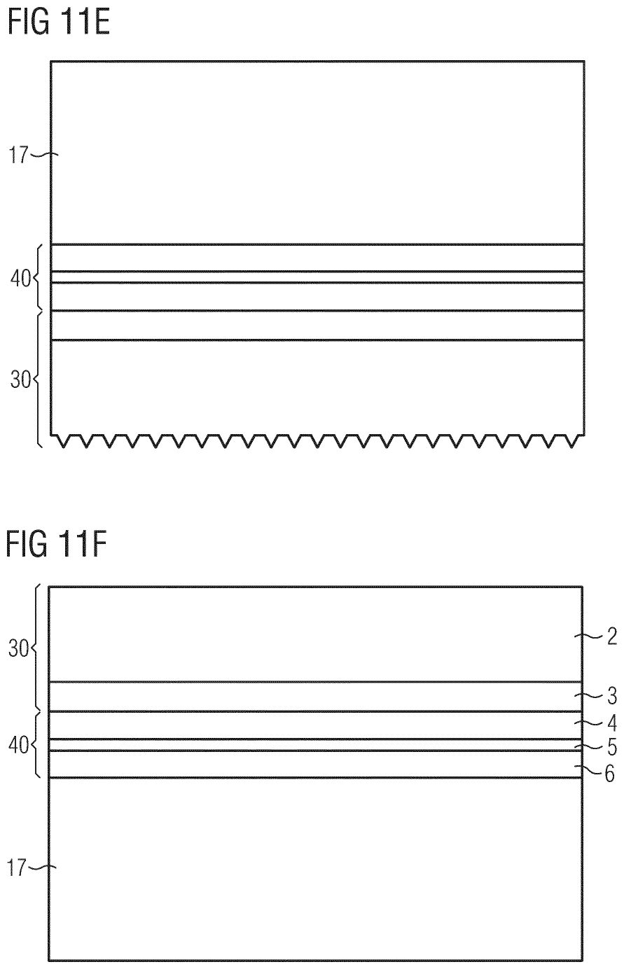

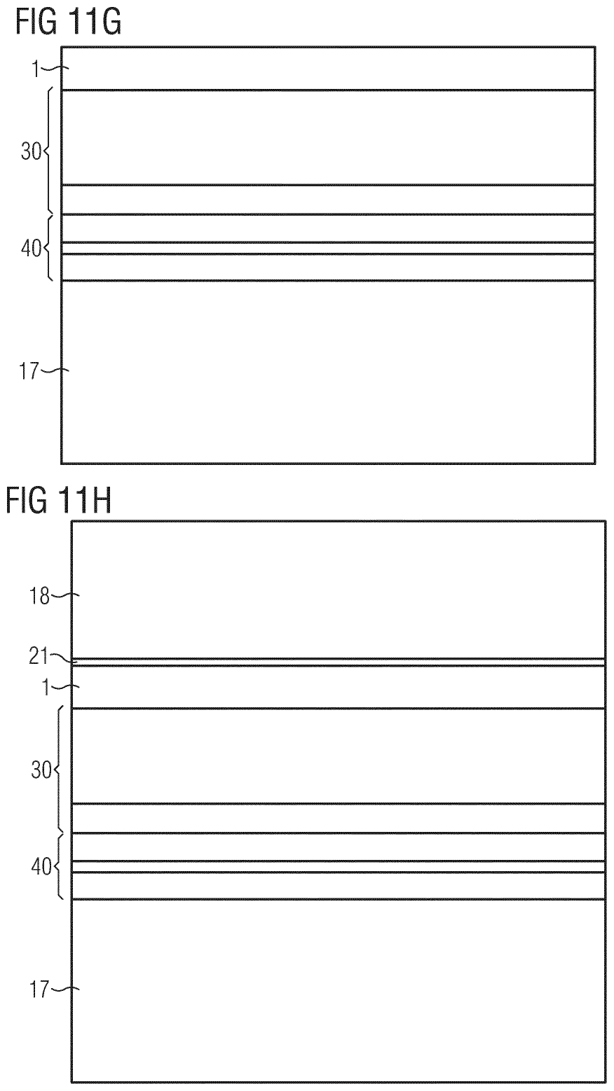

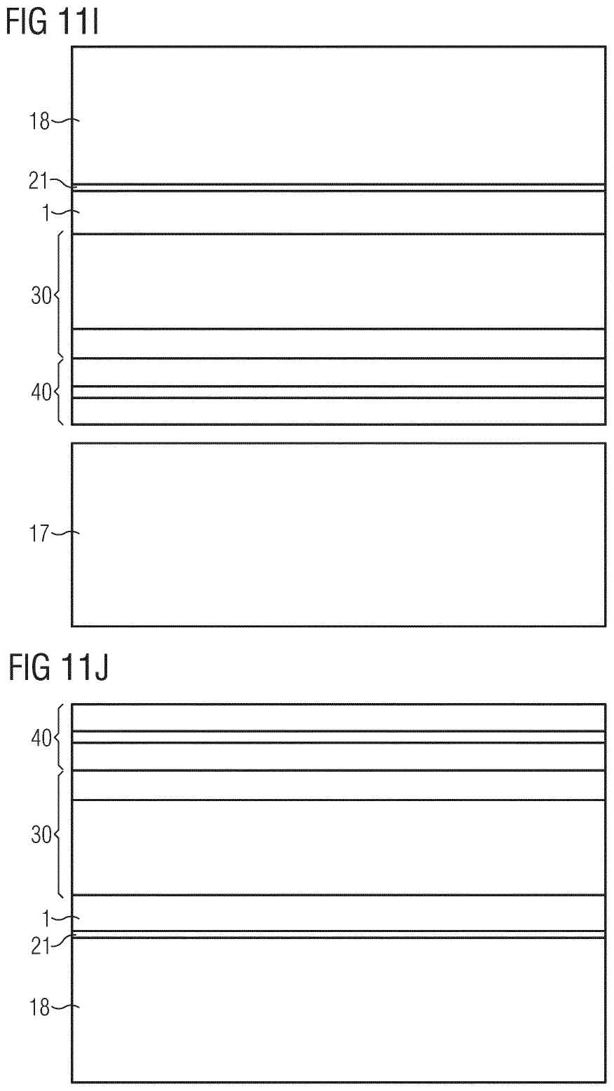

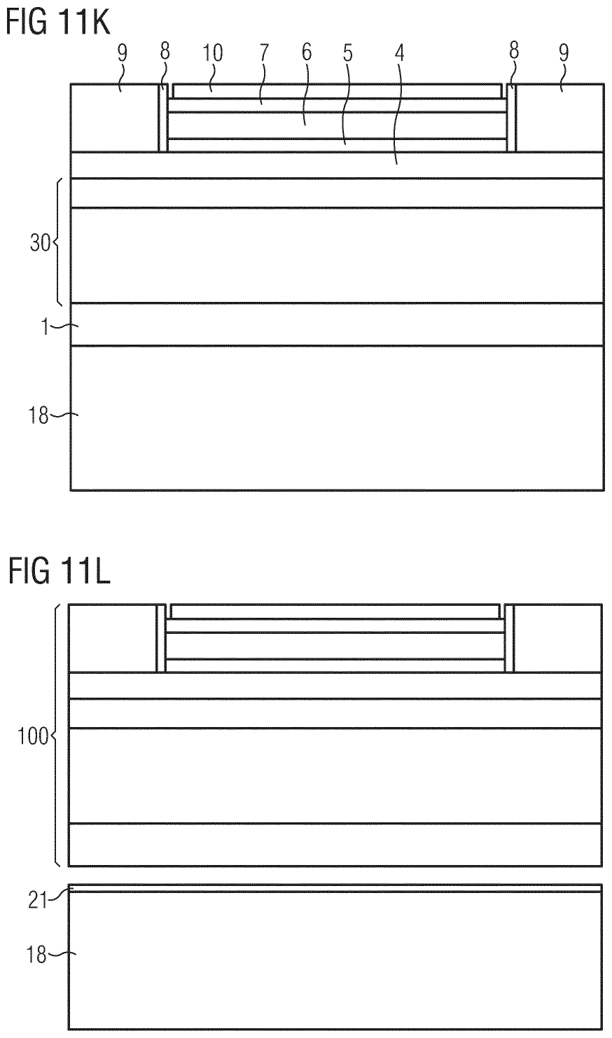

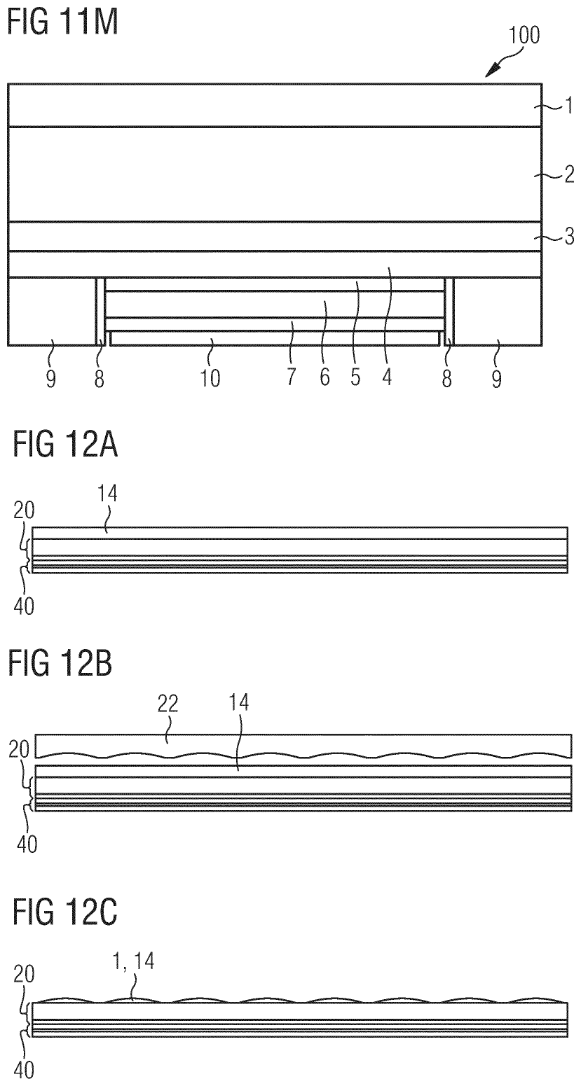

FIGS. 11A, 11B, 11C, 11D, 11E, 11F, 11G, 11H, 11I, 11J, 11K, 11L and 11M show a further embodiment of the method described herein for manufacturing a radiation-emitting device.

The method steps shown in FIGS. 11A and 11B correspond to the steps described in FIGS. 10A and 10B.

In a subsequent step, FIG. 11C, an auxiliary carrier 17 is applied onto the side of the semiconductor layer sequence 40 facing away from the carrier 30.

Subsequently, FIG. 11D, the sapphire carrier 2 is thinned. By using an auxiliary carrier 17, the carrier 30 may be thinner in this example embodiment of the method for manufacturing a radiation-emitting device than in the example embodiment of a manufacturing method described in FIG. 10. For example, the sapphire carrier 2 may be thinned to a target thickness of a maximum of 150 μm, in particular a maximum of 120 μm.

FIG. 11E shows an embodiment in which the thinned carrier 30 is patterned on the side facing away from the semiconductor layer sequence 40 before the starting layer 14 is applied.

FIG. 11F shows a variant of the radiation-emitting device 100 of FIG. 11E rotated by 180° about the main axis of extension.

Subsequently, FIG. 11G, the method steps of FIGS. 10D and 10E are carried out to form a radiation outcoupling layer 1 based on quartz glass on the side of the carrier 30 facing away from the semiconductor layer sequence 40.

FIG. 11H shows the radiation-emitting device after the application of a separating layer 21 on the radiation outcoupling layer 1 and a further auxiliary carrier 18 on the separating layer 21. The separating layer 21 may also be applied additionally or alternatively to the auxiliary carrier 18.

In a subsequent method step, FIG. 11I, the auxiliary carrier 17 is detached from the semiconductor layer sequence 40. The auxiliary carrier 17 and the semiconductor layer sequence 40 may be separated using wet-chemical methods or laser lift-off, for example.

FIG. 11J shows the radiation-emitting device 100 after the method step described in FIG. 11I, rotated by 180° about the main axis of extension.

FIG. 11K corresponds to the method step described in FIG. 10F. FIG. 11K additionally shows an embodiment in which the further auxiliary carrier 18 may be applied to the radiation outcoupling layer 1 without an additional separating layer 21.

In a subsequent method step, FIG. 11L, the further auxiliary carrier 18 is separated from the radiation outcoupling layer 1. The further auxiliary carrier 18 and the semiconductor layer sequence 40 may be separated, for example, by wet-chemical methods or by laser lift-off.

FIG. 11M shows a finished radiation-emitting device 100 which differs from the radiation-emitting device 100 shown in FIG. 10G only in its thickness. This is achieved by the different target thicknesses in the thinning processes of the sapphire substrate 2, FIGS. 10C and 11D.

FIGS. 12A, 12B and 12C show a further embodiment of a method described herein for manufacturing a radiation-emitting device.

FIG. 12A shows a device arrangement as in FIG. 10D, which is produced using the method steps 10A to 10D. FIG. 12A differs from FIG. 10D in that the method steps 10A to 10D in FIG. 12 are applied to a substrate 20. The structure of the substrate 20 corresponds to the structure of the carrier 30. Only the size of the substrate 20 along a main extension plane is a multiple of the size of the carrier 30. Thus, a plurality of radiation-emitting devices 100 may be produced simultaneously in the method shown in FIG. 12. These may then be separated.

In a subsequent step, FIG. 12B, the starting layer 14 is patterned. As shown herein, this may mean that the starting layer 14 is patterned in the shape of a lens. The lenticular patterning is transferred to the radiation-emitting device 100 by a replication wafer 22. The transfer of the structure of the replication wafer 22 to the starting layer 14 may be carried out, for example, by means of a pressing process.

FIG. 12C shows the lenticular starting layer 14 on the substrate 20. The lenticular starting layer 14 may be formed into a lenticular radiation outcoupling layer 1.

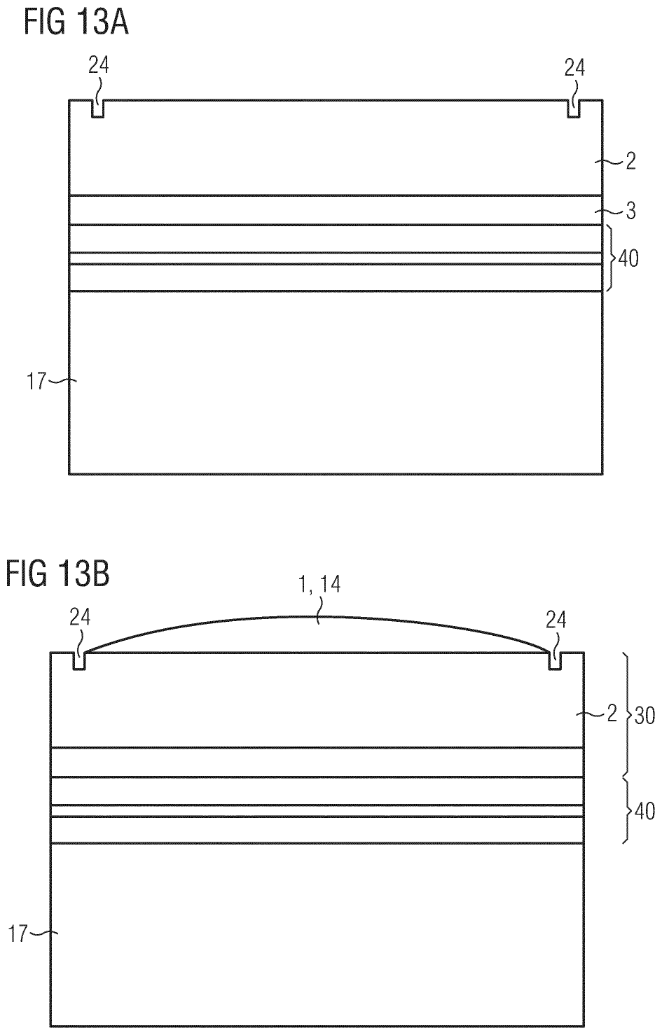

FIGS. 13A and 13B show a further embodiment of a method for manufacturing a radiation-emitting device 100 comprising a lenticular radiation outcoupling layer 1.

FIG. 13A shows a radiation-emitting device 100 that may be manufactured using the method steps shown in FIGS. 11A, 11B, 11C and 11D. Subsequent to these steps, FIG. 13A, notches 24 are made in the sapphire carrier 2 by means of mechanical processing, for example by sawing or lasering. These notches 24 serve as stop edges for forming lenticular structures.

FIG. 13B shows the function of the notches 24 as stop edges for forming lenticular structures. The starting layer 14 spreads out on the substrate 30 up to the notches 24 and forms a lenticular structure. The starting layer 14 may then be formed into a lenticular radiation outcoupling layer 1.

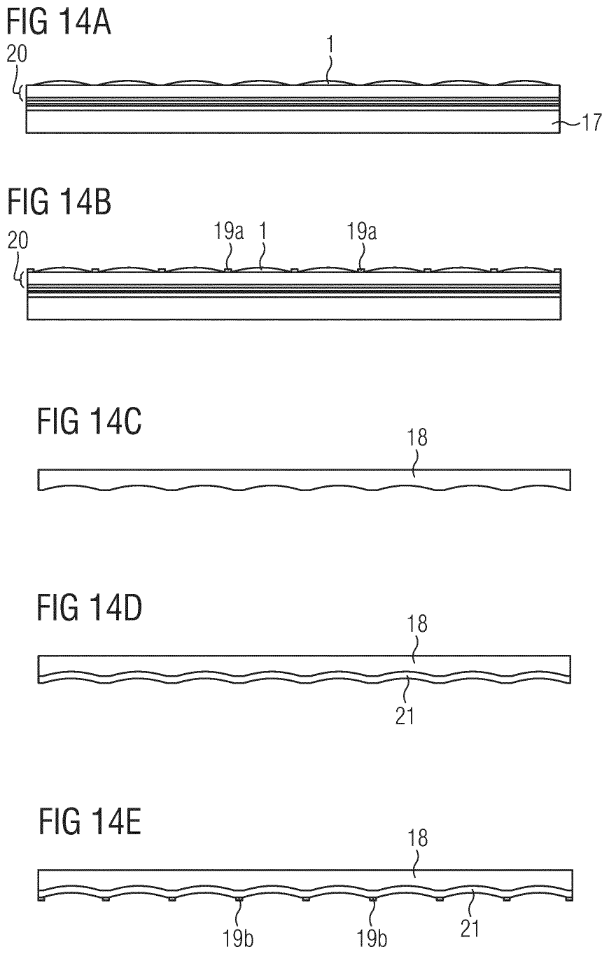

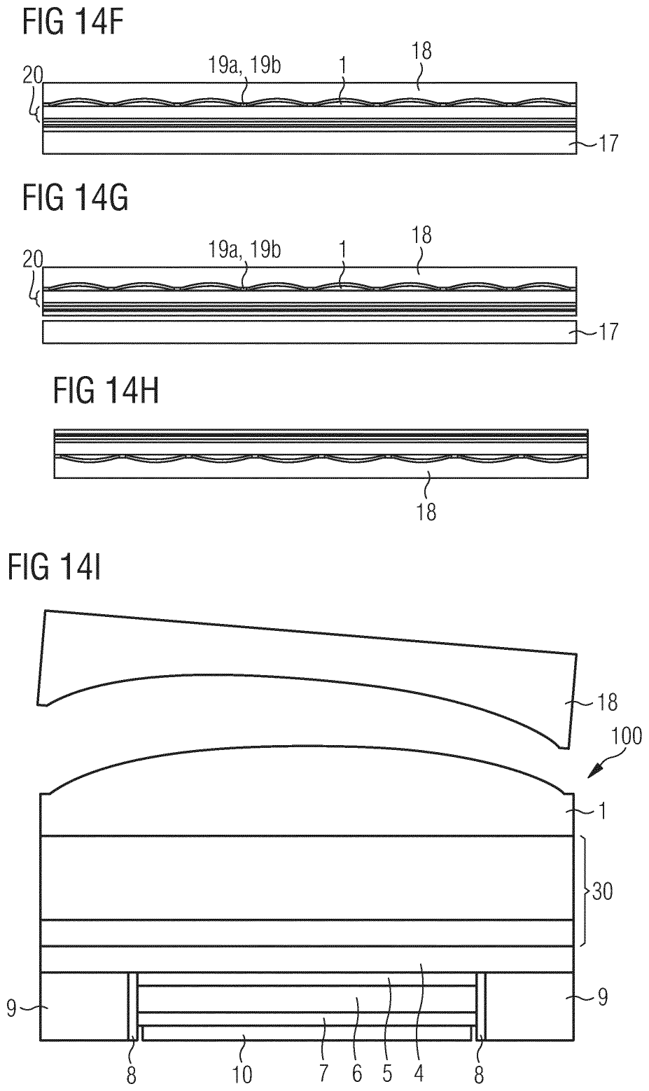

FIG. 14, in method steps A-I, shows an embodiment of a method for manufacturing a radiation-emitting device 100. The device shown in FIG. 14A follows on from the method steps described in FIG. 12 or FIG. 13 and shows a patterned radiation outcoupling surface 1.

FIG. 14B shows a step in which metal webs 19a are applied onto the substrate 20 in the spaces between the radiation outcoupling layer 1. These may include AuSn, for example. The metal webs 19a are applied, for example, by sputtering using a mask.

In FIG. 14C, a further auxiliary carrier 18 is provided. The further auxiliary carrier 18 has a pattern which is complementary to a pattern of the radiation outcoupling layer 1 facing the auxiliary carrier 18.

Then, FIG. 14D, a coating for a subsequent separation process is applied onto the further auxiliary carrier 18. The coating may include SiN, for example. The coating is a release layer 21, for example. The coating may also have a protective function. For example, the coating may be required for a laser lift-off process.

FIG. 14E shows a step in which metal webs 19b are applied onto the further auxiliary carrier 18 in places.

After the further auxiliary carrier 18 and the device produced in FIG. 14B have been prepared for wafer bonding via the metal webs 19a, 19b, the carriers are joined together, FIG. 14F. This is achieved, for example, by AuSn:Au bonding.

FIG. 14G shows a step in which the auxiliary carrier 17 is removed from the semiconductor layer sequence 40.

Subsequently, FIG. 14H, a method step described in FIG. 10F is carried out, not shown, in which metallization and electrical contacting are applied. The further auxiliary carrier 18 is then removed, for example by wet-chemical means or by laser lift-off.

In order to obtain a radiation-emitting device 100, the substrate 20 is finally, FIG. 14I, separated into individual carriers 30. For example, the device array is sawn up.

The features and example embodiments described in conjunction with the figures may be combined with one another in accordance with further example embodiments, even if not all combinations are explicitly described. Furthermore, the embodiments described in conjunction with the figures may alternatively or additionally have further features as described in the general part.

The present disclosure is not limited to the description with reference to the embodiments. Rather, the present disclosure includes any new feature as well as any combination of features, which includes in particular any combination of features in the claims, even if this feature or combination itself is not explicitly disclosed in the claims or example embodiments.

### LIST OF REFERENCES

1 Radiation outcoupling layer
2 sapphire carrier
3 buffer layer
4 n-doped semiconductor layer
5 active region
6 p-doped semiconductor layer
7 metallization
8 passivation layer
9 n-contact
10 p-contact
11 surface of the radiation outcoupling layer
12 top side of the carrier/substrate
13 bottom side of the carrier/substrate
14 starting layer
15 SiO₂ particles
16 matrix material
17 auxiliary carrier
18 further auxiliary carrier
19a metal webs of the substrate
19b metal webs of the further auxiliary carrier
20 substrate
21 separating layer
22 replication wafers
23 layer transition
24 notch
25 bonding layer
30 carrier
semiconductor layer sequence
100 radiation emitting device

1. A radiation-emitting device, comprising a carrier formed to comprise sapphire and/or AlN,
a semiconductor layer sequence applied onto the carrier,
a radiation outcoupling layer, which is arranged on the side of the carrier facing away from the semiconductor layer sequence,
wherein
the semiconductor layer sequence comprises an active region for generating electromagnetic radiation,
the radiation outcoupling layer has a refractive index for the electromagnetic radiation generated by the active region, the refractive index being between a refractive index of the carrier and a refractive index of a medium surrounding the device, and
the radiation outcoupling layer is based on quartz glass,
the radiation-emitting device is configured to emit electromagnetic radiation in the UV range.

2. (canceled)

3. The radiation-emitting device according to claim 1,
wherein the side of the carrier facing and/or facing away from the radiation outcoupling layer is patterned.

4. The radiation-emitting device according to claim 1,
wherein the side of the radiation outcoupling layer facing away from the carrier is roughened.

5. The radiation-emitting device according to claim 1, wherein the radiation outcoupling layer comprises or forms an optical element on the carrier.

6. The radiation-emitting device according to claim 1,
wherein a bonding layer is arranged between the carrier and the radiation outcoupling layer, and the bonding layer comprises or consists of SiO₂.

7. The radiation-emitting device according to claim 1,
wherein metallic contacts for external contacting are arranged on the side of the semiconductor layer sequence facing away from the radiation outcoupling layer.

8. The radiation-emitting device according to claim 1,
wherein a metallization is applied onto the side of the semiconductor layer sequence facing away from the carrier.

9. The radiation-emitting device according to claim 1, wherein the carrier has a thickness of at most 400 μm.

10. A method of manufacturing a radiation-emitting device, comprising:
epitaxially growing a semiconductor layer sequence on a substrate formed to comprise sapphire and/or AlN,
forming a radiation outcoupling layer based on quartz glass directly on the substrate, on the side of the substrate facing away from the semiconductor layer sequence.

11. The method according to claim 10,
wherein forming the radiation outcoupling layer based on quartz glass comprises:
applying a starting layer comprising SiO₂ particles in a matrix material onto the side of the substrate facing away from the semiconductor layer sequence,
removing the matrix material,
sintering the SiO₂ particles to produce a radiation outcoupling layer based on quartz glass.

12. The method according to claim 11, wherein the matrix material comprises a polymer.

13. The method for producing a radiation-emitting device according to claim 10, wherein the substrate is thinned directly after epitaxially growing the semiconductor layer sequence on the substrate.

14. The method according to claim 10, wherein
after epitaxially growing the semiconductor layer sequence on the substrate, an auxiliary carrier is applied onto the semiconductor layer sequence on the side of the semiconductor layer sequence facing away from the substrate the substrate is thinned,
after the radiation outcoupling layer has been formed, a further auxiliary carrier is applied onto the radiation outcoupling layer,
the auxiliary carrier is removed,
metallic contacts are formed on the side of the semiconductor layer sequence facing away from the radiation outcoupling layer, and
the further auxiliary carrier is removed.

15. The method according to claim 14,
wherein after forming the radiation outcoupling layer, the method comprises:
applying metal webs onto the substrate in spaces of the radiation outcoupling layer,
wherein the further auxiliary carrier has a structure which is complementary to a structure of the radiation outcoupling layer facing the auxiliary carrier,
wherein the further auxiliary support has metal webs in places, and
wherein the metal webs of the further auxiliary carrier are connected to the metal webs of the substrate.

16. The method according to claim 10, wherein the starting layer is applied onto the substrate in a patterned manner such that it has lenticular structures.

17. The method according to claim 16, further comprising:
forming notches in the substrate before the starting layer is applied onto the substrate, the notches serving as stop edges for forming the lenticular structures.

18. The method according to claim 10, wherein the substrate is patterned before applying the starting layer.

19. The method according to claim 10, wherein the radiation outcoupling layer comprises or forms an optical element, which is implemented as an optical lens, on the substrate.

20. A radiation-emitting device, comprising
a carrier formed to comprise sapphire and/or AlN,
a semiconductor layer sequence applied onto the carrier,
a radiation outcoupling layer, which is arranged on the side of the carrier facing away from the semiconductor layer sequence,
wherein
the semiconductor layer sequence comprises an active region for generating electromagnetic radiation,
the radiation outcoupling layer has a refractive index for the electromagnetic radiation generated by the active region, the refractive index being between a refractive index of the carrier and a refractive index of a medium surrounding the device,
the radiation outcoupling layer is based on quartz glass,
the radiation outcoupling layer comprises or forms an optical element, that is implemented as on optical lens, on the carrier, and
the radiation outcoupling layer is directly adjacent to the carrier.
